(19) United States
(12) Patent Application Publication
(10) Pub. No.: US 2015/0194434 A1
(43) Pub. Date: Jul. 9, 2015

(54) MEMORY DEVICE AND METHODS OF FORMING MEMORY DEVICE AND SEMICONDUCTOR DEVICE

(71) Applicant: eMemory Technology Inc., Hsinchu (TW)

(72) Inventor: Te-Hsun Hsu, Hsinchu County (TW)

(21) Appl. No.: 14/445,072

(22) Filed: Jul. 29, 2014

Related U.S. Application Data
(60) Provisional application No. 61/925,187, filed on Jan. 8, 2014.

(51) Int. Cl. H01L 27/115; H01L 21/28

(52) U.S. Cl. CPC H01L 27/11524; H01L 21/28273

(57) ABSTRACT

A method of forming a memory device is provided. A first conductive layer is formed on a substrate. The first conductive layer is patterned to form at least two trenches extending along a first direction therein. An insulating layer is formed on surfaces of the trenches and on a surface of the first conductive layer. A second conductive layer is formed on the insulating layer. The second conductive layer is patterned to form at least one control gate extending along a second direction different from the first direction. The first conductive layer is patterned to form at least one floating gate below the control gate and to form a select gate adjacent to the control gate.

### CROSS-REFERENCE TO RELATED APPLICATION

This application claims the priority benefits of U.S. provisional application Ser. No. 61/925,187, filed on Jan. 8, 2014. The entirety of the above-mentioned patent application is hereby incorporated by reference herein and made a part of this specification.

### BACKGROUND OF THE INVENTION

1. Field of Invention

The present invention relates to a semiconductor device and a method of forming the same, and more generally to a memory device and a method of forming the same.

2. Description of Related Art

A non-volatile memory device provides the advantages of multiple entries, retrievals and erasures of data, and is able to retain the stored information even when the electrical power is off. As a result, a non-volatile memory device is widely used in personal computers and consumer electronic products.

As the semiconductor technology steps into a deep sub-micron or nano-scale generation, the size of a device has to be shrunk to meet the demand for high-density products. However, in the conventional process, the floating gate of a memory device is defined by a single photomask, so the edge rounding issue is serious. Besides, the distance between the floating gate and the select gate is designed based on the spacing rule since they are usually formed in the same patterning process by the same photomask. The edge rounding issue and the spacing rule impose limitations on the size reduction of the memory device.

### SUMMARY OF THE INVENTION

Accordingly, the present invention provides a memory device and a forming method thereof, in which an overlay rule instead of a spacing rule is adopted to design the distance between the floating gate and the select gate, so that the device size can be significantly reduced to meet the customer requirements.

The present invention provides a method of forming a memory device. A first conductive layer is formed on a substrate. The first conductive layer is patterned to form at least two trenches extending along a first direction therein. An insulating layer is formed on surfaces of the trenches and on a surface of the first conductive layer. A second conductive layer is formed on the insulating layer. The second conductive layer is patterned to form at least one control gate extending along a second direction different from the first direction. The first conductive layer is patterned to form at least one floating gate below the control gate and to form a select gate adjacent to the control gate.

According to an embodiment of the present invention, the step of patterning the first conductive layer to form the trenches includes forming a first photoresist layer on the first conductive layer, removing a first portion of the first conductive layer by using the first photoresist layer as a mask, and removing the first photoresist layer.

According to an embodiment of the present invention, the step of patterning the second conductive layer to form the control gate includes the following steps. A hard mask layer and a second photoresist layer are formed on the second conductive layer. Portions of the hard mask layer, the second conductive layer and the insulating layer are removed by using the second photoresist layer as mask, so as to form at least one stacked structure on the first conductive layer, wherein the stacked structure includes, from bottom to top, an inter-gate insulating layer, the control gate and a hard mask pattern. The second photoresist layer is removed.

According to an embodiment of the present invention, the method further includes forming a first spacer on a sidewall of the stacked structure.

According to an embodiment of the present invention, the step of patterning the first conductive layer to form the floating gate and the select gate includes the following steps. A third photoresist layer is formed on the first conductive layer adjacent to the stacked structure. A second portion of the first conductive layer is removed by using the hard mask pattern and the first spacer as a mask, so as to form the floating gate below the control gate. A third portion of the first conductive layer is removed by using the third photoresist layer as a mask, so as to form the select gate adjacent to the control gate. The third photoresist layer is removed.

According to an embodiment of the present invention, the method further includes forming an interfacial layer on the substrate before the step of forming the first conductive layer.

According to an embodiment of the present invention, the method further includes forming a plurality of doped regions in the substrate after the step of patterning the first conductive layer to form the floating gate and the select gate.

According to an embodiment of the present invention, the floating gate and the doped regions have different conductivity types.

According to an embodiment of the present invention, the insulating layer includes a single layer or a multi-layer structure.

The present invention further provides a method of forming a semiconductor device. At least two trenches, extending along a first direction, are formed in a material layer. At least one stripe-shaped pattern, extending along a second direction different from the first direction, is formed on the material layer. A portion of the material layer is removed by using the stripe-shaped pattern as a mask and another portion of the material layer is simultaneously removed.

According to an embodiment of the present invention, each of the material layer and the stripe-shaped pattern includes a conductive material.

According to an embodiment of the present invention, the material layer and the stripe-shaped pattern are separated from each other by an insulating layer.

According to an embodiment of the present invention, the another portion of the material layer is removed by using a photoresist layer as a mask.

The present invention further provides a memory device including a control gate, floating gates, an inter-gate insulating layer and a select gate. The control gate is disposed on a substrate. The floating gates are disposed between the control gate and the substrate, wherein a width of each floating gate is greater than a width of the control gate. The inter-gate insulating layer is disposed between the control gate and each of the floating gates. The select gate is disposed on the substrate adjacent to the control gate.

According to an embodiment of the present invention, the memory device further includes tunnelling dielectric layers respectively disposed between the floating gates and the substrate, a gate dielectric layer disposed between the select gate and the substrate, and doped regions disposed in the substrate adjacent to the floating gate and the select gate.

According to an embodiment of the present invention, the floating gate and the doped regions have different conductivity types.

According to an embodiment of the present invention, no doped region is present in the substrate between the floating gate and the select gate.

According to an embodiment of the present invention, the memory device further includes a spacer disposed on the floating gates and on a sidewall of the control gate.

According to an embodiment of the present invention, the control gate further extends into gaps between two adjacent floating gates.

According to an embodiment of the present invention, the inter-gate insulating layer is a single layer or a multi-layer structure.

In view of the above, with the method of the invention, each floating gate is defined by three photomasks rather than a single photomask, so the conventional edge rounding is not observed. Besides, the adjacent floating gate and the select gate are designed based on an overlay rule rather than a spacing rule, so the size of the memory device can be significantly reduced. In the present invention, only three photomasks are required to define the floating gate, control gate and select gate, so the production cost can be significantly reduced and the competitive advantage can be easily achieved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a memory device according to an embodiment of the present invention.

FIG. 2A to FIG. 2G are schematic cross-sectional views of a method of forming a memory device taken along the lines I-I′ and II-II′ of FIG. 1.

FIG. 2G-1 is a schematic cross-sectional view of a memory device according to another embodiment of the present invention.

FIG. 3 is a schematic top view of a first photoresist layer in the step of FIG. 2B.

FIG. 4 is a schematic top view of a second photoresist layer in the step of FIG. 2C.

FIG. 5 is a schematic top view of a third photoresist layer in the step of FIG. 2F.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

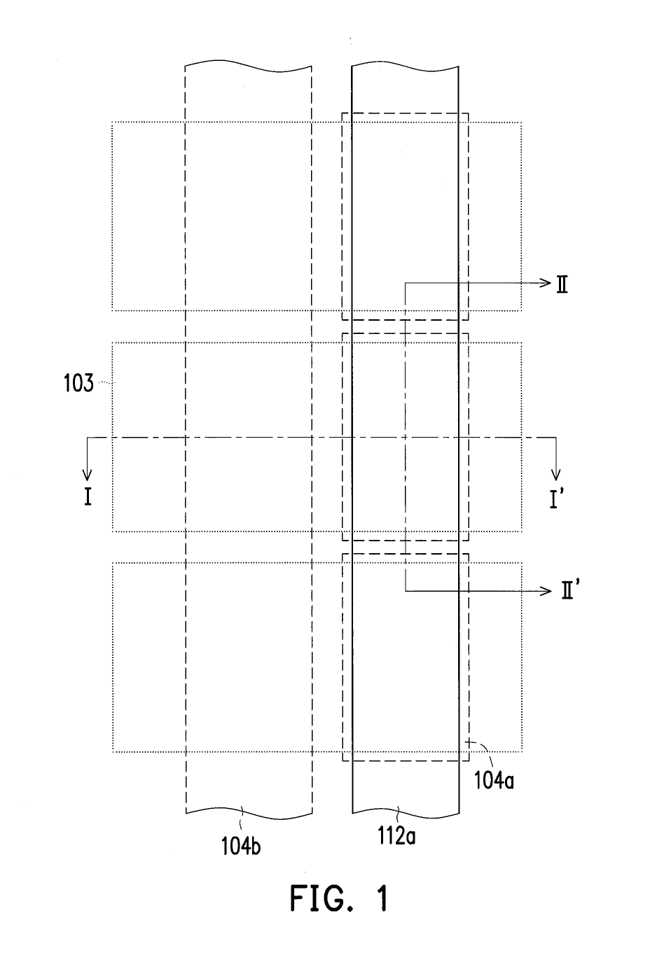

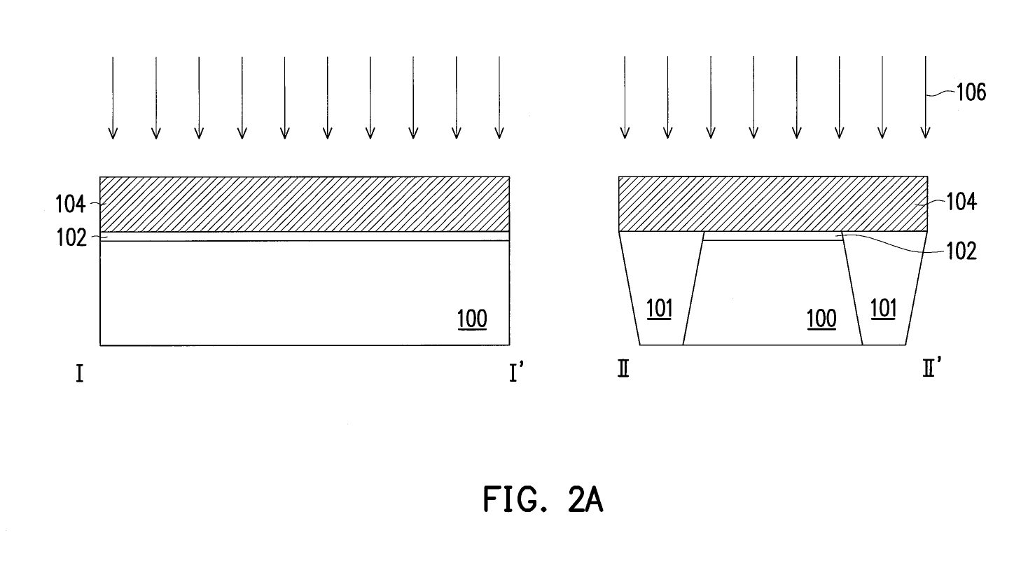

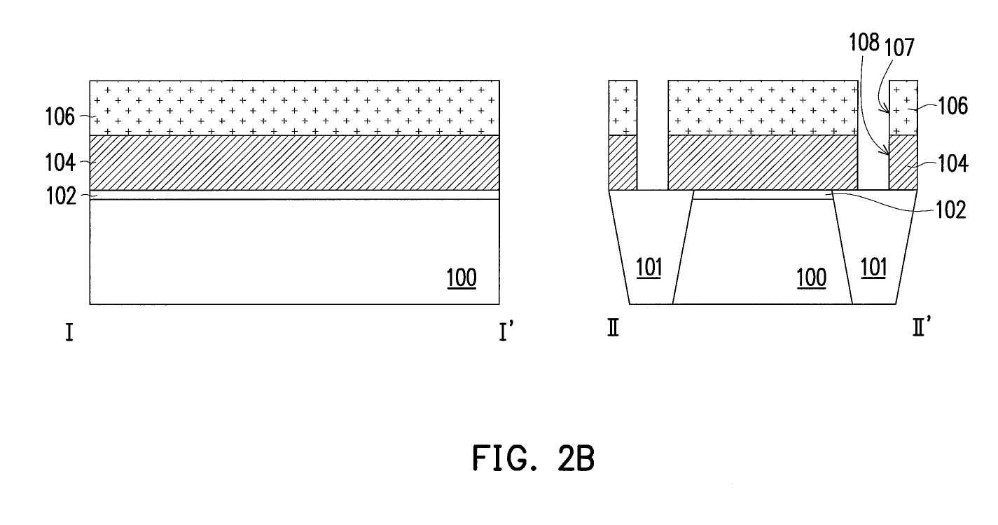

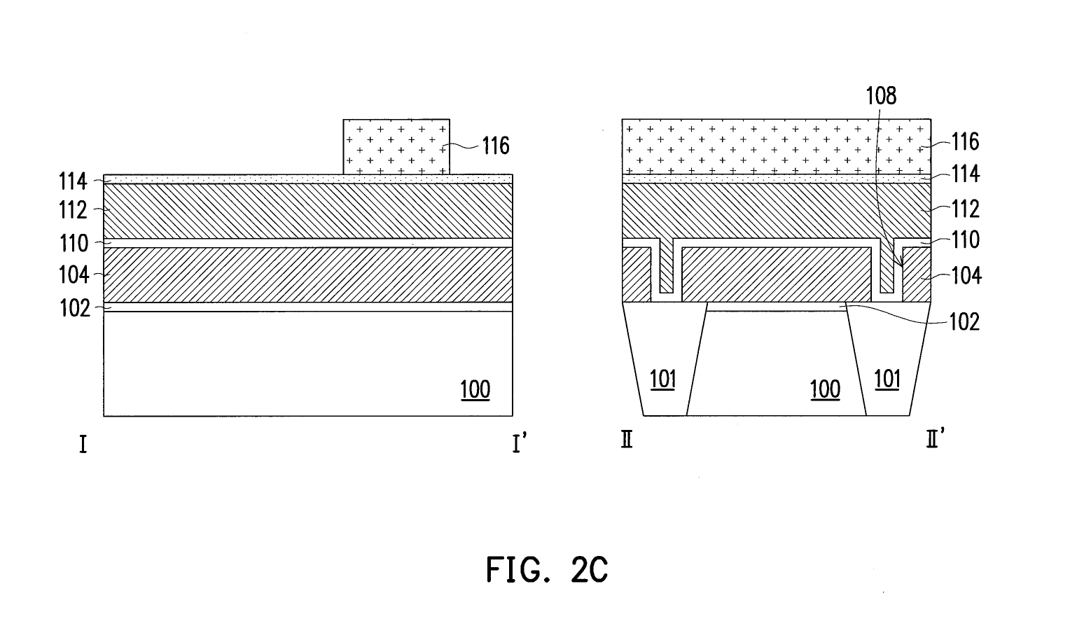

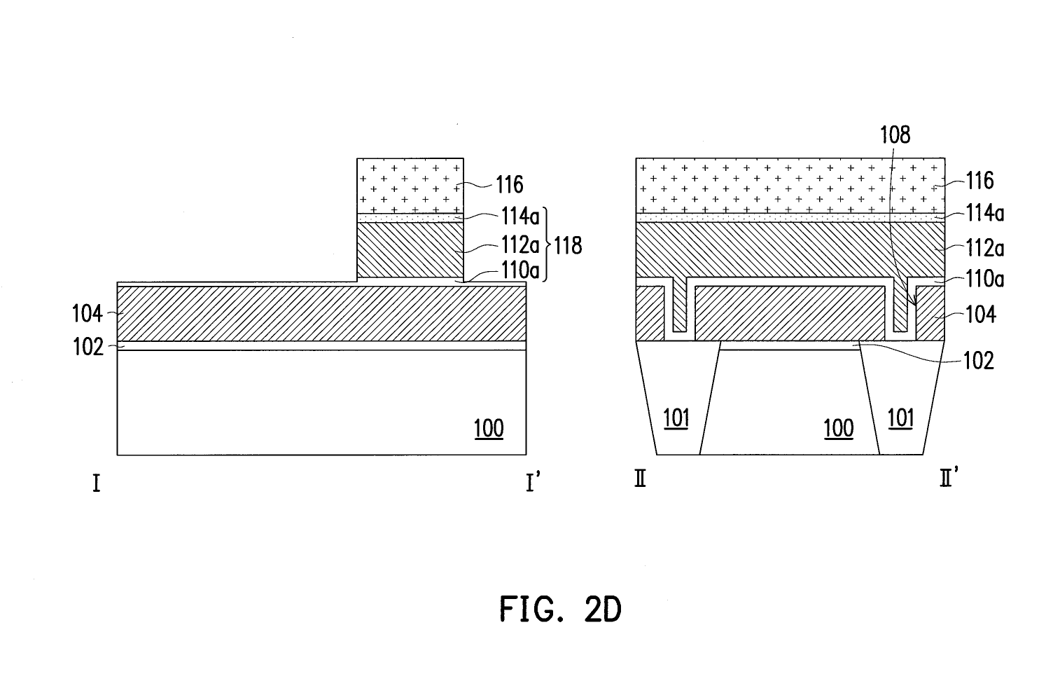

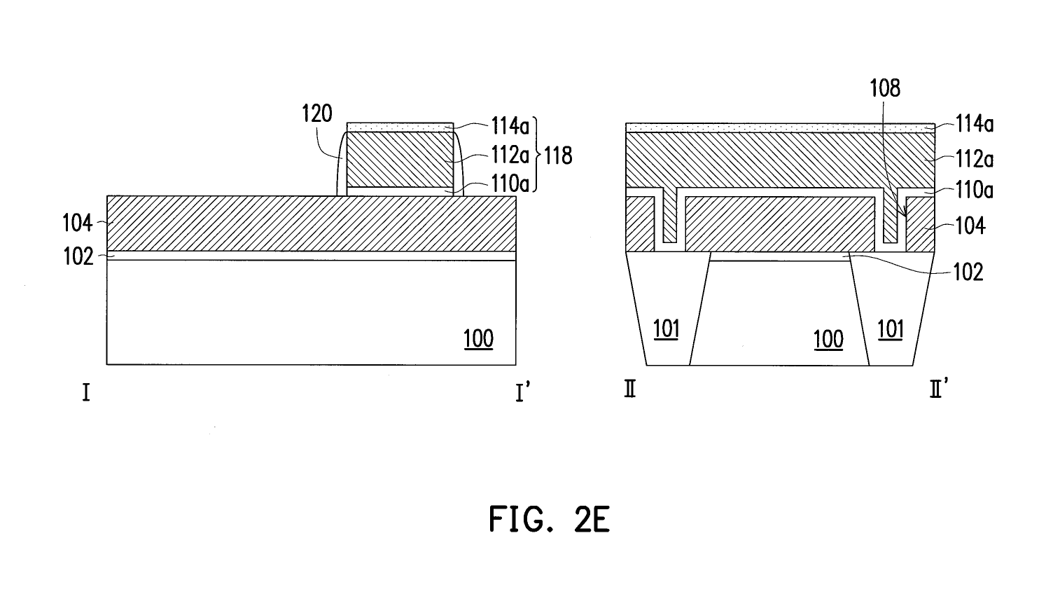

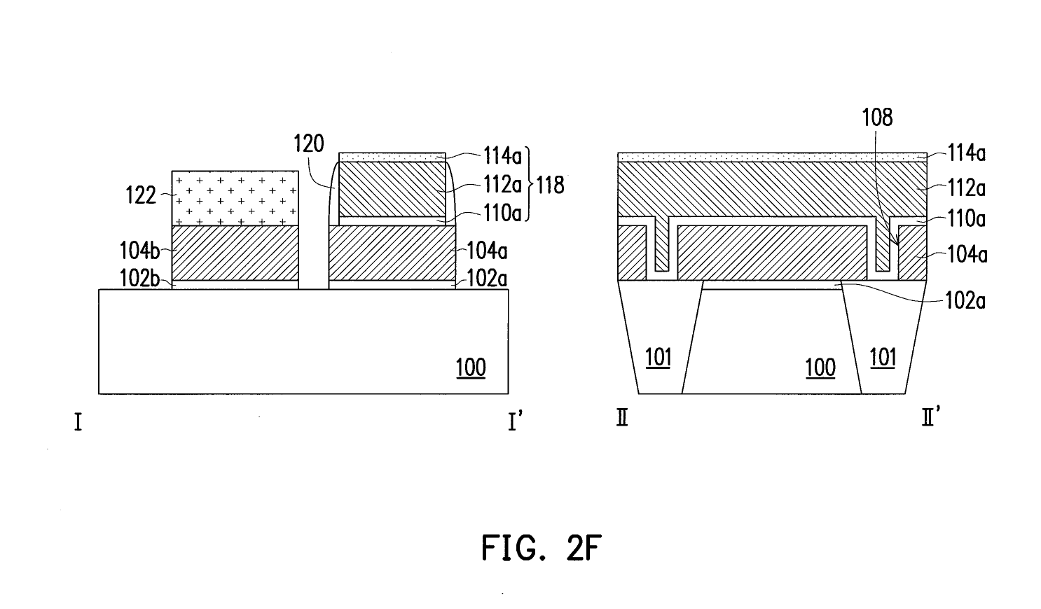

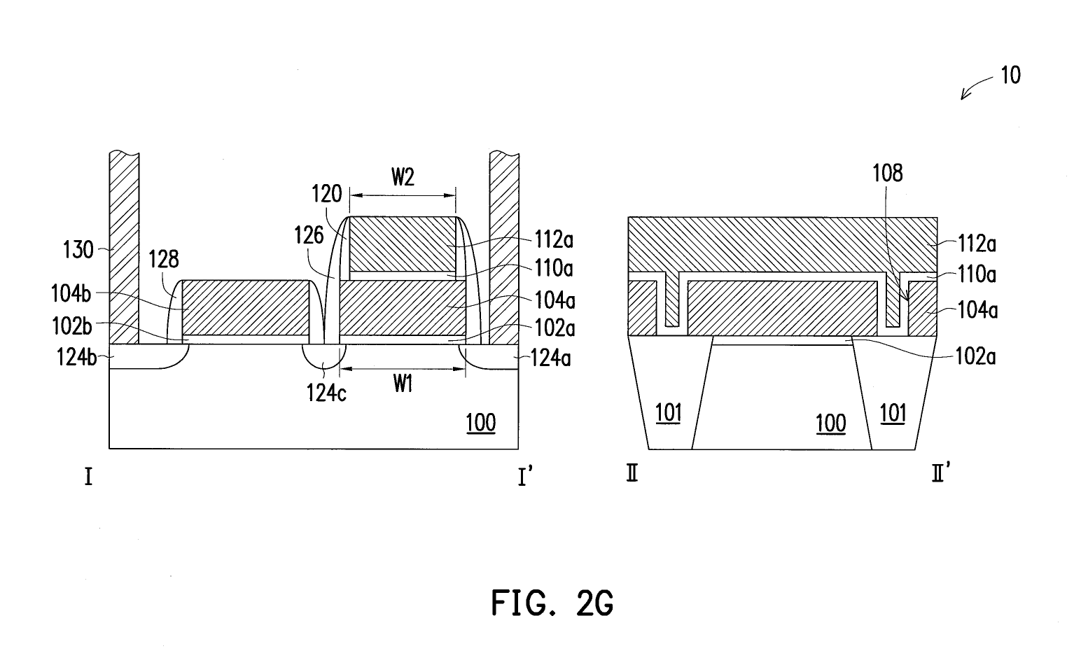

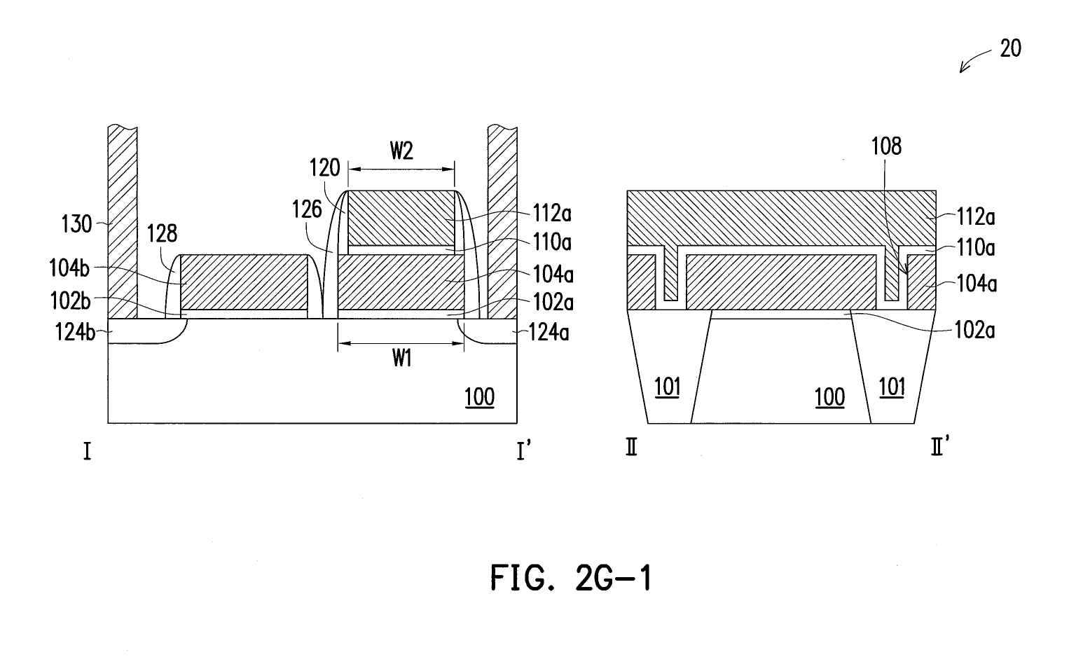

FIG. 1 is a schematic top view of a memory device according to an embodiment of the present invention, in which only active areas, floating gates, a control gate and a select gate are depicted for clarity and convenience of illustration. FIG. 2A to FIG. 2G are schematic cross-sectional views of a method of forming a memory device taken along the lines I-I′ and II-II′ of FIG. 1.

Referring to FIG. 2A, a substrate 100 is provided. The substrate 100 can be a semiconductor substrate, such as a silicon substrate. The substrate 100 has at least two shallow trench isolation (STI) structures 101 therein. The two adjacent SIT structures 101 define an active area 103 therebetween, as shown in FIG. 1. In an embodiment, the substrate 100 can be a first-type substrate having a second-type well region (not shown) in the active area 103. The first-type substrate can be a P-type substrate, and the second-type well region can be an N-type well region.

Thereafter, an interfacial layer 102 and a first conductive layer 104 are sequentially formed on the substrate 100. The interfacial layer 102 includes silicon oxide and the forming method thereof includes performing a thermal oxidation process. The first conductive layer 104 includes polysilicon, metal or a combination thereof, and the forming method thereof includes performing a deposition process (e.g. CVD). Afterwards, an ion implantation process 106 is performed to dope the first conductive layer 104. In an embodiment, the first conductive layer 104 is doped with a second-type dopant, such as an N-type dopant.

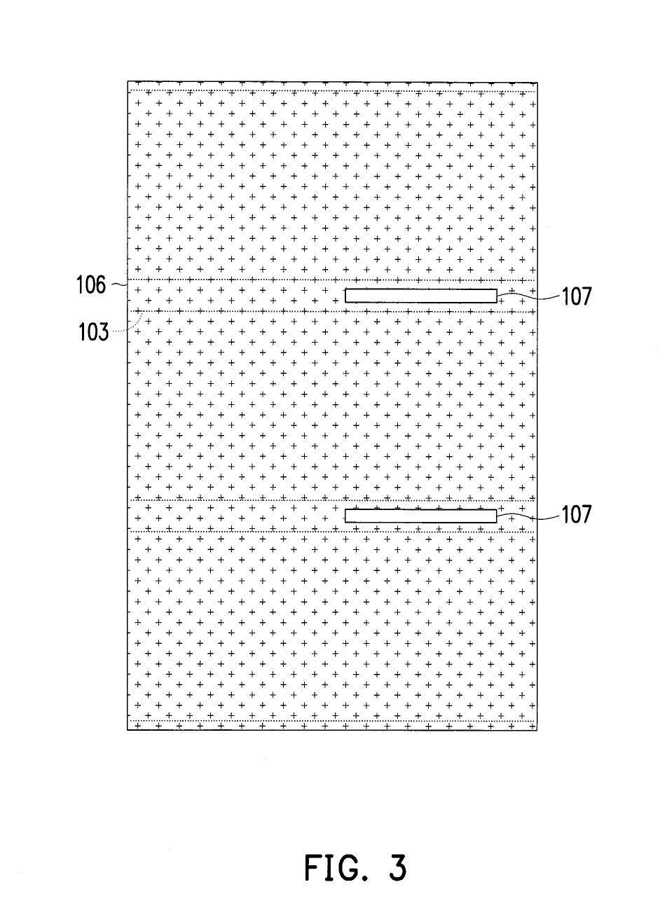

Referring to FIG. 2B, a first photoresist layer 106 is formed on the first conductive layer 104 through a first photolithography process with a first photomask (not shown). The first photomask can be referred to as a “floating gate photomask”. FIG. 3 is a schematic top view of the first photoresist layer 106. The first photoresist layer 106 has opening patterns 107 therein. Thereafter, a first portion of the first conductive layer 104 is removed by using the first photoresist layer 106 as a mask, so as to form trenches 108 therein. Specifically, the opening patterns 107 of the first photoresist layer 106 are transferred to the first conductive layer 104, and therefore the trenches 108 are formed in the first conductive layer 104. The first photoresist layer 106 is then removed. In view of the foregoing step in FIG. 2B, the first conductive layer 104 is patterned to form at least two trenches 108 therein. The trenches 108 extend along a first direction (e.g. X-direction).

Referring to FIG. 2C, an insulating layer 110 is formed on surfaces of the trenches 108 and on a surface of the first conductive layer 104. The insulating layer 110 can be a single layer or a multi-layer structure. In an embodiment, the insulating layer 110 can be a single silicon oxide layer. In another embodiment, the insulating layer 110 can be an ONO composite layer including a bottom oxide layer, a nitride layer and a top oxide layer. The method of forming the insulating layer 110 includes performing at least one deposition process (e.g. CVD).

Thereafter, a second conductive layer 112 is formed on the insulating layer 110 filling the trenches 108. The second conductive layer 112 includes polysilicon, metal or a combination thereof, and the forming method thereof includes performing a deposition process (e.g. CVD). Afterwards, an ion implantation process (not shown) is performed to dope the second conductive layer 112. In an embodiment, the second conductive layer 112 is doped with a first-type dopant, such as a P-type dopant. In another embodiment, the second conductive layer 112 can be doped with a second-type dopant, such as an N-type dopant, upon the process requirements.

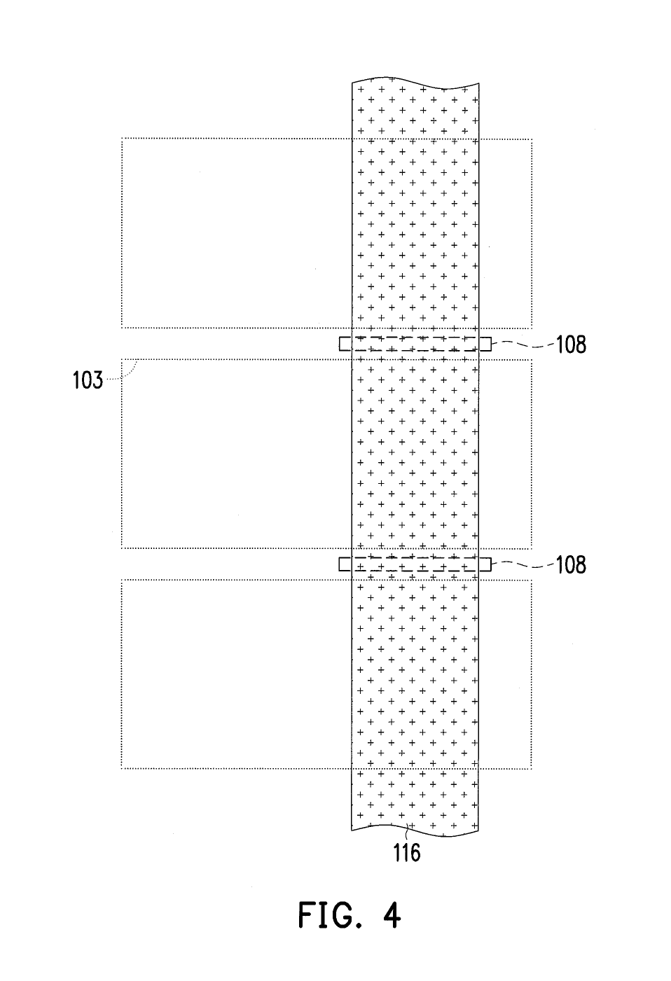

Still referring to FIG. 2C, a hard mask layer 114 is formed on the second conductive layer 112. The hard mask layer 114 includes silicon nitride and the forming method thereof includes performing a deposition process (e.g. CVD). Next, a second photoresist layer 116 is formed on the hard mask layer 114 through a second photolithography process with a second photomask (not shown). The second photomask can be referred to as a “control gate photomask”. FIG. 4 is a schematic top view of the second photoresist layer 116.

Referring to FIG. 2D, portions of the hard mask layer 114, the second conductive layer 112 and the insulating layer 110 are removed by using the second photoresist layer 116 as mask, so as to form at least one stacked structure 118 on the first conductive layer 104. The stacked structure 118 includes, from bottom to top, an inter-gate insulating layer 110a, the control gate 112a and a hard mask pattern 114a. It is noted that partial insulating layer 110 outside the stacked structure 118 can remain for protecting the underlying layer (e.g. first conductive layer 104). In an embodiment, when the insulating layer 110 is a single silicon oxide layer, about half portion of the insulating layer 110 outside the stacked structure 118 is removed, and the remaining portion of the insulating layer 110 serves as a protection layer. In another embodiment, when the insulating layer 110 is an ONO composite layer, the top oxide layer and the nitride layer outside the stacked structure 118 are removed, and the bottom oxide layer serves as a protection layer.

In view of the steps in FIG. 2C and FIG. 2D, the second conductive layer 112 is patterned to form at least one control gate 112a extending along a second direction (e.g. Y-direction) different from the first direction. In this embodiment, the second direction is perpendicular to the first direction, but the present invention is not limited thereto.

Referring to FIG. 2E, a first spacer 120 is formed on a sidewall of the stacked structure 118. The first spacer 120 is configured to protect the inter-gate insulating layer 110a and the control gate 112a. The first spacer 120 includes silicon oxide. The method of forming the first spacer 120 includes forming a spacer material layer (not shown) on the substrate 100, and removing a portion of the spacer material layer through an anisotropic etching process. In an embodiment, the partial insulating layer 110 outside the stacked structure 118 can be simultaneously removed during the formation of the first spacer 120.

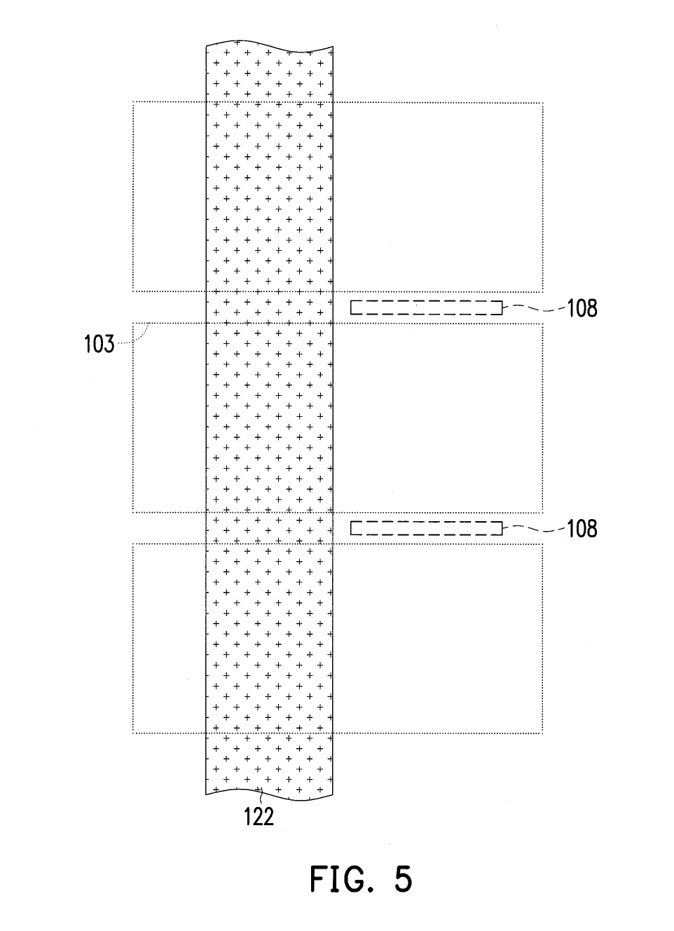

Referring to FIG. 2F, a third photoresist layer 122 is formed on the first conductive layer 104 adjacent to the stacked structure 118. The third photoresist layer 122 exposes the region where the control gate 112a is formed. The third photoresist layer 122 is formed through a third photolithography process with a third photomask (not shown). The third photomask can be referred to as a “select gate photomask”. FIG. 5 is a schematic top view of the third photoresist layer 122. Thereafter, a second portion of the first conductive layer 104 is removed by using the hard mask pattern 114a and the first spacer 120 as a mask, so as to form a floating gate 104a below the control gate 112a. At the same time, a third portion of the first conductive layer 104 is removed by using the third photoresist layer 122 as a mask, so as to form a select gate 104b adjacent to the control gate 112a. The third photoresist layer 122 is then removed. In view of the foregoing step in FIG. 2F, the first conductive layer 104 is patterned to form at least one floating gate 104a below the control gate 112a and to form a select gate 104b adjacent to the control gate 112a. In addition, during the patterning step of the first conductive layer 104, the interfacial layer 102 is simultaneously patterned to form a tunnelling dielectric layer 102a below the floating gate 104a and form a gate dielectric layer 102b below the select gate 104b. Herein, the tunnelling dielectric layer 102a, the floating gate 104a, the inter-gate insulating layer 110a and the control gate 112a form a memory cell transistor (e.g. an ETOX transistor), and the gate dielectric layer 102b and the select gate 104b form a select transistor. The memory device 10 of this embodiment can be regarded as a two-transistor (2T) structure including a memory cell transistor and a select transistor.

Referring to FIG. 2G, a plurality of doped regions 124a-124c is formed in the substrate 100 adjacent to the floating gate 104a and the select gate 104b. Specifically, one of the doped regions (i.e. doped region 124a) is disposed in the substrate 100 adjacent to the memory cell transistor, and another of the doped regions (i.e. doped region 124b) is disposed in the substrate 100 adjacent to the select transistor. In an embodiment, the select transistor and the memory cell transistor share one of the doped regions (i.e. doped region 124c), as shown in FIG. 2G. In another embodiment, when the memory cell transistor is disposed close enough to the select transistor, no doped region is required therebetween, as shown in FIG. 2G-1. The method of forming the doped regions 124a-124c includes performing an ion implantation process. In an embodiment, the doped regions 124 include a first-type dopant, such as a P-type dopant.

Thereafter, a second spacer 126 is formed on a sidewall of the memory cell transistor, and a third spacer 128 is formed on a sidewall of the select transistor. The method of forming the second and third spacers 126 and 128 includes forming a spacer material layer (not shown) on the substrate 100, and removing a portion of the spacer material layer through an anisotropic etching process. The memory device 10 of the present invention is thus completed. The steps after the formation of the second and third spacers 126 and 128 include forming a dielectric layer to cover the substrate 100, forming contact plugs 130 in the dielectric layer to electrically connect to the doped regions 124a-124b etc. are well known to people having ordinary skill in the art, and the details are not iterated herein.

In this embodiment, the N-type floating gate and the P-type doped regions are provided with different conductivity types, resulting in a higher threshold voltage. Therefore, the channel width can be designed shorter to compensate for the higher threshold voltage. In such manner, the dimension of the device can be reduced, and a high-density product can be obtained.

In the memory device of the present invention, each floating gate 104a is defined by three photomasks (i.e. first, second and third photomasks in FIGS. 2B, 2C and 2F) rather than a single photomask, so the conventional edge rounding is not observed. Besides, since the adjacent floating gate 104a and the select gate 104b are formed by different photomasks, the distance between the floating gate 104a and the select gate 104b can be designed based on an overlay rule rather than a spacing rule. Therefore, the size of the memory device can be significantly reduced.

The said embodiment in which the first-type is P-type and the second-type is N-type is provided for illustration purposes, and is not construed as limiting the present invention. In another embodiment, the first-type can be N-type and the second-type can be P-type.

The present invention further provides a method of forming a semiconductor device, which includes forming at least two trenches (e.g. trenches 108 in FIG. 2B), extending along a first direction, in a material layer (e.g. first conductive layer 104 in FIG. 2B); forming at least one stripe-shaped pattern (e.g. control gate 112a in FIG. 2D), extending along a second direction different from the first direction, on the material layer; and removing a portion of the material layer by using the stripe-shaped pattern as a mask and simultaneously removing another portion of the material layer by using a photomask layer (e.g. third photokmask layer 122 in FIG. 2F) as a mask. In an embodiment, each of the material layer and the stripe-shaped pattern includes a conductive material, such as polysilicon, metal or a combination thereof. Besides, the material layer and the stripe-shaped pattern are separated from each other by an insulating layer (e.g. the inter-gate insulating layer 110a).

In the said embodiment, the method of forming a semiconductor device is implemented for fabricating a memory device, but the present invention is not limited thereto. The method can be applied to any suitable semiconductor device as long as the designer desires to define adjacent patterns on the same layer with an overlay rule instead of a spacing rule.

The structure of the memory device can be illustrated below with reference to FIG. 1 and FIG. 2G. The memory device 10 includes a substrate 100, a control gate 112a, multiple floating gates 104a, an inter-gate insulating layer 110a and a select gate 104b. The control gate 112a is disposed on the substrate 100. The floating gates 104a are disposed between the control gate 112a and the substrate 100, wherein a width W1 of each floating gate 104a is greater than a width W2 of the control gate 112a. In an embodiment, a first spacer 120 is further included in the memory device 10, and the spacer 120 is disposed on the floating gates 104a and on a sidewall of the control gate 112a. The inter-gate insulating layer 110a is disposed between the control gate 112a and each of the floating gate 104a. The inter-gate insulating layer 110a is a single layer or a multi-layer structure. The select gate 104b is disposed on the substrate 100 adjacent to the control gate 112a.

The memory device 10 further includes a plurality of tunnelling dielectric layers 102a, a gate dielectric layer 102b and a plurality of doped regions 124a-124c. The tunnelling dielectric layers 102a are respectively disposed between the floating gates 104a and the substrate 100. The gate dielectric layer 102b is disposed between the select gate 104b and the substrate 100. In an embodiment, the tunnelling dielectric layers 102a and the gate dielectric layer 102b are formed by the same material and have the same thickness. The doped regions 124a-124c are disposed in the substrate 100 adjacent to the floating gates 104a and the select gate 104b. In an embodiment, the adjacent floating gate 104a and the select gate 104b share one doped region 124c therebetween, as shown in FIG. 2G. In another embodiment, no doped region is present in the substrate 100 between the adjacent floating gate 104a and the select gate 104b, as shown in FIG. 2G-1.

Besides, the floating gates 104a and the doped regions 124a-124c have different conductivity types. Such configuration is beneficial to further reduce the dimension of the device. In addition, the control gate 112a further extends into the gaps between the two adjacent floating gates 104a. Since the contact area between the floating gates and the control gate is increased, the gate coupling ratio (GCR) of the memory device can be enhanced. Accordingly, the operation voltage of the memory can be reduced and the efficiency of the device can be increased.

In summary, in the method of the invention, each floating gate is defined by three photomasks rather than a single photomask, so the conventional edge rounding is not observed, and the shortest distance from the active area to the floating gate can be minimized. Besides, since the adjacent floating gate and the select gate are formed by different photomasks, the distance between the floating gate and the select gate can be designed based on an overlay rule rather than a spacing rule. Therefore, the size of the memory device can be significantly reduced, and a high-density product can be obtained.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of forming a memory device, comprising:
forming a first conductive layer on a substrate;
patterning the first conductive layer to form at least two trenches therein, wherein the trenches extend along a first direction;
forming an insulating layer on surfaces of the trenches and on a surface of the first conductive layer;
forming a second conductive layer on the insulating layer;
patterning the second conductive layer to form at least one control gate extending along a second direction different from the first direction; and
patterning the first conductive layer to form at least one floating gate below the control gate and to form a select gate adjacent to the control gate.

2. The method of claim 1, wherein the step of patterning the first conductive layer to form the trenches comprises:
forming a first photoresist layer on the first conductive layer;
removing a first portion of the first conductive layer by using the first photoresist layer as a mask; and
removing the first photoresist layer.

3. The method of claim 1, wherein the step of patterning the second conductive layer to form the control gate comprises:
forming a hard mask layer and a second photoresist layer on the second conductive layer;
removing portions of the hard mask layer, the second conductive layer and the insulating layer by using the second photoresist layer as mask, so as to form at least one stacked structure on the first conductive layer, wherein the stacked structure comprises, from bottom to top, an inter-gate insulating layer, the control gate and a hard mask pattern; and
removing the second photoresist layer.

4. The method of claim 3, further comprising forming a first spacer on a sidewall of the stacked structure.

5. The method of claim 4, wherein the step of patterning the first conductive layer to form the floating gate and the select gate comprises:
forming a third photoresist layer on the first conductive layer adjacent to the stacked structure;
removing a second portion of the first conductive layer by using the hard mask pattern and the first spacer as a mask, so as to form the floating gate below the control gate; and
removing a third portion of the first conductive layer by using the third photoresist layer as a mask, so as to form the select gate adjacent to the control gate; and
removing the third photoresist layer.

6. The method of claim 1, further comprising forming an interfacial layer on the substrate before the step of forming the first conductive layer.

7. The method of claim 1, further comprising forming a plurality of doped regions in the substrate after the step of patterning the first conductive layer to form the floating gate and the select gate.

8. The method of claim 7, wherein the floating gate and the doped regions have different conductivity types.

9. The method of claim 8, wherein the insulating layer comprises a single layer or a multi-layer structure.

10. A method of forming a semiconductor device, comprising:
forming at least two trenches, extending along a first direction, in a material layer;
forming at least one stripe-shaped pattern, extending along a second direction different from the first direction, on the material layer; and
removing a portion of the material layer by using the stripe-shaped pattern as a mask and simultaneously removing another portion of the material layer.

11. The method of claim 10, wherein each of the material layer and the stripe-shaped pattern comprises a conductive material.

12. The method of claim 11, wherein the material layer and the stripe-shaped pattern are separated from each other by an insulating layer.

13. The method of claim 10, wherein the another portion of the material layer is removed by using a photoresist layer as a mask.

14. A memory device, comprising:
a control gate, disposed on a substrate;
a plurality of floating gates, disposed between the control gate and the substrate, wherein a width of each floating gate is greater than a width of the control gate;
an inter-gate insulating layer, disposed between the control gate and each of the floating gates; and
a select gate, disposed on the substrate adjacent to the control gate.

15. The memory device of claim 14, further comprising:
a plurality of tunnelling dielectric layers, respectively disposed between the floating gates and the substrate;
a gate dielectric layer, disposed between the select gate and the substrate; and
a plurality of doped regions, disposed in the substrate adjacent to the floating gate and the select gate.

16. The memory device of claim 15, wherein the floating gate and the doped regions have different conductivity types.

17. The memory device of claim 15, wherein no doped region is present in the substrate between the floating gate and the select gate.

18. The memory device of claim 14, further comprising a spacer disposed on the floating gates and on a sidewall of the control gate.

19. The memory device of claim 14, wherein the control gate further extends into gaps between two adjacent floating gates.

20. The memory device of claim 14, wherein the inter-gate insulating layer is a single layer or a multi-layer structure.
